(19) United States
(12) Patent Application Publication
(10) Pub. No.: US 2014/0096805 A1
(43) Pub. Date: Apr. 10, 2014

(54) FRAME-MOUNTED LIGHTING FOR A COLLAPSIBLE STRUCTURE

(71) Applicant: Paul J. Silva, Springfield, OR (US)

(72) Inventor: Paul J. Silva, Springfield, OR (US)

(21) Appl. No.: 13/646,539

(22) Filed: Oct. 5, 2012

(51) Int. Cl. E04H 15/10; H05K 13/00; B23P 11/00

(52) U.S. Cl. 135/91; 29/428; 29/825

(57) ABSTRACT

A collapsible structure comprises elongated frame members assembled together and one or more lighting elements, and can further comprise panels attached to the frame members to at least partially enclose the structure volume. The lighting elements are integrally mounted on the frame members to illuminate the structure volume or an area around the structure. The frame members can include an integral power source connected to the lighting elements. Frame members can comprise telescoping inner and outer frame members with the lighting elements integrally mounted on the inner frame member and retractable with the inner frame member to be enclosed within the outer frame member. Applying power to the lighting elements can illuminate a deployment area while assembling together the frame members.

### BACKGROUND

The field of the present invention relates to collapsible structures. In particular, frame-mounted lighting for such structures is disclosed herein.

A wide variety of collapsible structures (e.g., tents, portable enclosures or shelters, canopies, scaffolding, and so forth) are employed in a wide variety of deployment scenarios (e.g., camping, hunting, other recreation, emergency response, field medical, military, and so on). “Collapsible” denotes a structure intended to be readily erected at a deployment site and then later folded, disassembled, or otherwise collapsed or broken down again. Such structures are often intended to be readily transported from one deployment site to another.

Such collapsible structures can comprise a plurality of elongated frame members assembled together in a deployed arrangement to define a volume of the structure. Two or more or all of the frame members can be connected together by one or more articulated joints that permit the frame members to assume differing orientations with respect to one another, e.g., so that the structure can be “unfolded” into the deployed arrangement or “folded” into a collapsed arrangement. Instead or in addition, one or more or all of the frame members can be completely detached from the others in the collapsed arrangement. The collapsible structure can further comprise one or more panels arranged to be attached, with the frame members in the deployed arrangement, to one or more of the frame members so as to at least partially enclose the structure volume; the panels can include roof panels, side panels, internal partition panels, or floor panels. The panels can be substantially rigid but are often foldable, e.g., comprising sheets of foldable fabric or plastic. One or more or all of the panels can be arranged to remain at least partly attached to one or more of the frame members upon collapsing the structure. Instead or in addition, one or more or all of the panels can be detached completely from all of the frame members upon collapsing the structure.

### SUMMARY

A collapsible structure comprises a plurality of elongated frame members and one or more lighting elements. The plurality of elongated frame members are arranged to be assembled together in a deployed arrangement to define a volume of the structure. The one or more lighting elements are integrally mounted on one or more of the frame members and arranged to illuminate, with the frame members in the deployed arrangement, at least a portion of the structure volume or an area around the structure.

The one or more lighting elements can comprise one or more light-emitting diodes. One or more of the plurality of frame members can include an integral power source connected to one or more of the corresponding lighting elements. One or more of the plurality of frame members can comprise corresponding pairs of telescoping inner and outer frame members movable between an extended, deployed configuration and a retracted, non-deployed configuration, with the one or more lighting elements integrally mounted on the one or more corresponding inner frame members and arranged so that, with the corresponding frame members in the extended configuration, the lighting elements are exposed outside the corresponding outer frame members and, with the corresponding frame members in the retracted configuration, the lighting elements are enclosed within the corresponding outer frame members. The collapsible structure can further comprise one or more panels arranged to be attached, with the frame members in the deployed arrangement, to one or more of the frame members so as to at least partially enclose the structure volume.

A method comprises assembling together into the deployed arrangement the plurality of elongated frame members so as to define the structure volume. The one or more lighting elements are integrally mounted on one or more of the frame members and arranged to illuminate, with the frame members in the deployed arrangement, at least a portion of the structure volume or an area around the structure. The method can further comprise applying power to the one or more lighting elements so as to at least partly illuminate a deployment area while assembling together into the deployed arrangement the plurality of frame members.

Objects and advantages pertaining to collapsible, illuminated structures may become apparent upon referring to the exemplary embodiments illustrated in the drawings and disclosed in the following written description or appended claims.

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 illustrates schematically an example of a collapsible structure with panels attached to frame members.

FIG. 2 illustrates schematically assembled frame members of the exemplary structure of FIG. 1 with multiple integrally mounted lighting elements.

FIGS. 3A and 3B are schematic longitudinal cross sections of an exemplary elongated frame member with integrally mounted lighting elements and electrical conductors.

FIG. 4 is a schematic perspective view of an exemplary elongated frame member with integrally mounted lighting element and electrical connectors.

FIG. 5 is a schematic perspective view of an exemplary elongated frame member with integrally mounted lighting element and electrical conductors and a connector for an external power source.

FIGS. 6A-6D are schematic transverse cross sections of exemplary elongated frame members and integrally mounted lighting elements.

FIG. 7 is a schematic perspective view of an exemplary frame member having telescoping inner and outer frame members.

It should be noted that the embodiments depicted in this disclosure are shown only schematically, and that not all features may be shown in full detail or in proper proportion. Certain features or structures may be exaggerated relative to others for clarity. It should be noted further that the embodiments shown are exemplary only, and should not be construed as limiting the scope of the written description or appended claims.

### DETAILED DESCRIPTION OF EMBODIMENTS

It is often the case that lighting is employed to illuminate at least a portion of the structure volume or an area around the structure. It would be desirable to provide one or more lighting elements for achieving that illumination that are integrally mounted on one or more of the frame members of the collapsible structure. “Integrally mounted” is intended to convey that the lighting elements arrive at the deployment site already mounted on the corresponding frame members, whether or not they were originally provided as discrete subunits that were attached to the corresponding frame members prior to arriving at the deployment site. Collapsible structures are often deployed at sites that are less than ideally suited for extensive construction or assembly procedures, and in such circumstances it is advantageous to reduce the number of construction or assembly steps that must be performed at the deployment site. In addition, if the structure is deployed at night, it may be desirable to provide lighting elements integrally mounted on the frame members that can be activated during the assembly procedure, as described further below.

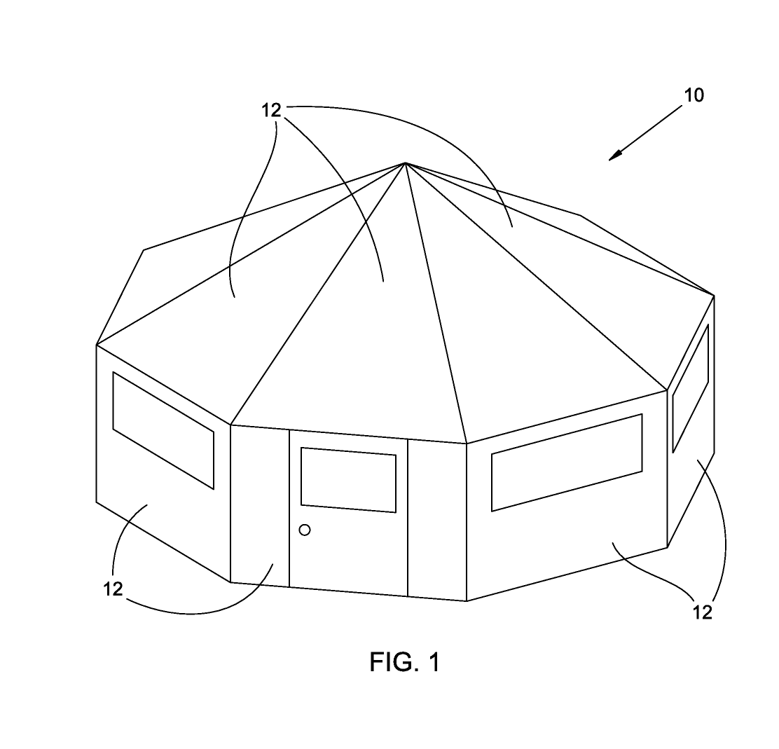

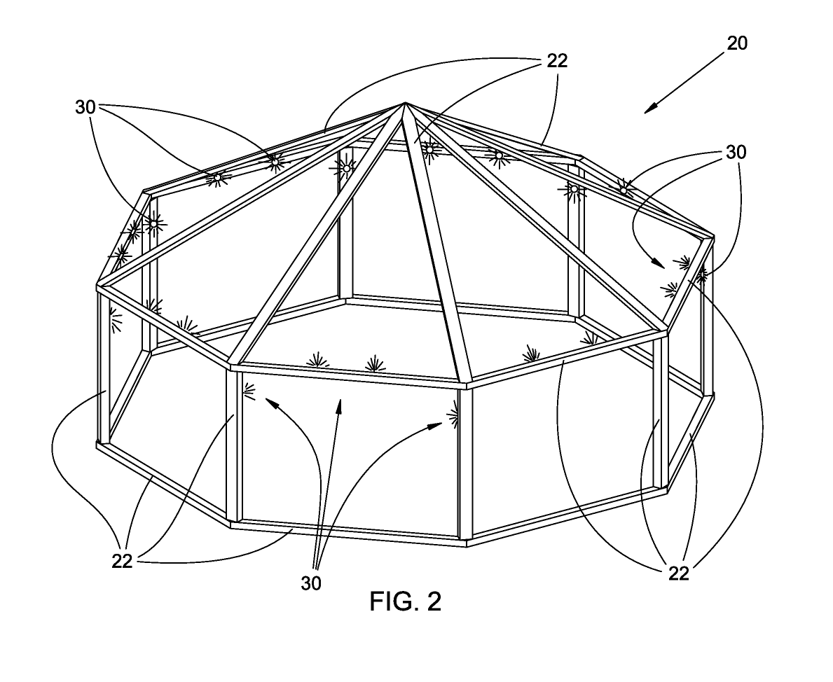

An exemplary collapsible structure 10 is illustrated schematically in FIGS. 1 and 2 and includes side and roof panels 12 (shown in FIG. 1) attached to a frame 20 (shown in FIG. 2). Frame 20 comprises a plurality of elongated frame members 22 assembled together in the so-called “deployed” arrangement of FIG. 2. In some examples the collapsible structure 10 comprises only frame 20 and lacks panels 12; in other examples panels 12 only partly enclose a structure volume defined by frame 20; in still other examples panels 12 enclose the structure volume substantially completely; all of those scenarios fall within the scope of the present disclosure or appended claims. The frame members 22 can comprise a suitably strong and rigid material (e.g., metal, wood, plastic, composite, combinations thereof, or other suitable materials) and can assume any shape, arrangement, or configuration suitable for forming the frame 20 and for supporting lighting elements 30 (as described further below). In the examples shown in the Figures all of the frame members 22 are substantially straight, however, curved or bent frame members shall also fall within the scope of the present disclosure or appended claims.

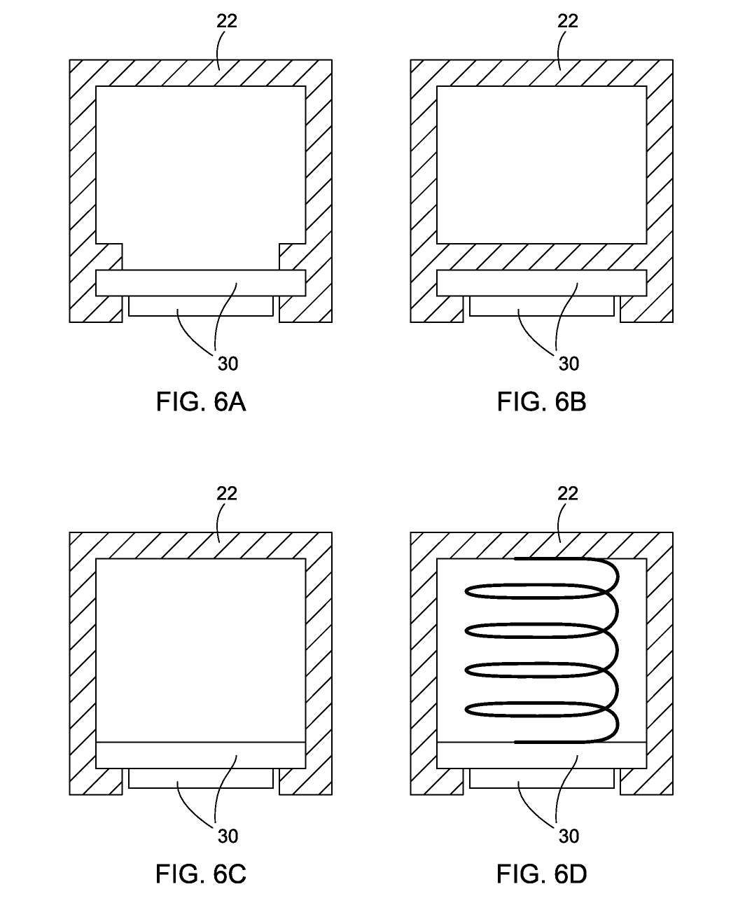

The exemplary frame members 22 shown in the Figures have generally U-shaped, generally rectangular transverse cross sections with the lighting elements 30 integrally mounted within the U-shaped cross sections; several variations are shown in FIGS. 6A-6D. However, any needed, desired, or suitable cross section, shape, or arrangement can be employed within the scope of the present disclosure or appended claims (e.g., rectangular, circular, oval, polygonal, and so forth). A given cross-section, including the examples of FIGS. 6A-6D, can represent the cross section of a frame member 22 along substantially its entire length or alternatively only along one or more segments where corresponding lighting elements 30 are located. In another example, the frame members 22 can be tubular with transverse holes for receiving therein the integrally mounted lighting elements 30. In another alternative example, the frame members 22 can comprise solid members with lighting elements 30 integrally mounted on an exterior surface thereof or within a recessed area of that exterior surface. Other suitable arrangements can be employed.

Any needed, desired, or suitable number of lighting elements 30 can be mounted on any one or more of the frame members 22 in any needed, desired, or suitable arrangement for providing illumination; the arrangement of the lighting elements 30 in FIG. 2 is only an illustrative example. The lighting elements 30 can be secured to the corresponding frame members 30 in any suitable way, which may or may not require any corresponding arrangement or adaptation of the frame member 22. In some examples, fasteners or adhesive can be employed; in other examples, a spring clip or retainer can be employed. In some of those examples corresponding holes can be provided on frame member 22 for receiving, e.g., a threaded or penetrating fastener or a spring clip. In the examples of FIGS. 6A-6D, the frame member 22 has a generally U-shaped cross section and further structural features for receiving the lighting elements 30. In FIG. 6A, the lighting element 30 is received in bilateral slots within the frame member 22. The arrangement of FIG. 6B is similar except for the addition of a cross member across the U-shaped frame member 22 (which creates a longitudinal channel within the frame member that is separate from the slot that receives the lighting element 30). In FIG. 6C, an interference fit holds the lighting element 30 in place within the frame member 22. In FIG. 6D a compression spring urges the lighting element 30 against inner surfaces of the frame member 22, holding the lighting element 30 in place. In any of the examples, the lighting element 30 can be held in place so that it is readily movable to another location along the frame member 22 (e.g., a loose-fitting lighting element 30 in FIGS. 6A or 6B, or the example of FIG. 6D if the spring is compressed further), or can be substantially fixed in place and not readily moveable (e.g., interference fit or adhesive in FIGS. 6A-6C).

Any needed, desired, or suitable number of lighting elements 30 can be integrally mounted on one or more of the frame members 22 in any suitable arrangement for illuminating at least a portion of the structure volume or an area around the structure. If panels 12 are present, lighting elements 30 can be mounted to illuminate the interior of the structure, an exterior area around the structure, or both, depending on the purpose of the illumination to be provided. In the illustrative example of FIG. 2, the lighting elements 30 are integrally mounted on vertical and horizontal wall frame members 22 and arranged to illuminate the structure volume (i.e., the interior of the structure enclose by panels 12). Lighting elements 30 can also be integrally mounted on roof frame members 22 if needed, desired, or suitable.

Any suitable type of light source can be employed for lighting elements 30, including but not limited to incandescent, fluorescent, gas discharge, and semiconductor light sources. Due to their small size, low power consumption, and relatively high light output, light-emitting diodes (LEDs) are well-suited for employment as lighting elements 30. Colored or white LEDs can be employed as needed, desired, or suitable, noting that “white” LEDs typically are a combination of several different colored LEDs chosen to produce light that appears white to a human observer. LED-based lighting elements 30 can each include a single LED or a cluster of LEDs. LED-based lighting elements 30 can each include an integral battery power source or can receive power from a discrete power source; such a discrete power source can be integrated into the corresponding frame member 22 (separate from the integrated lighting elements 30) or can be an external power source (discussed further below).

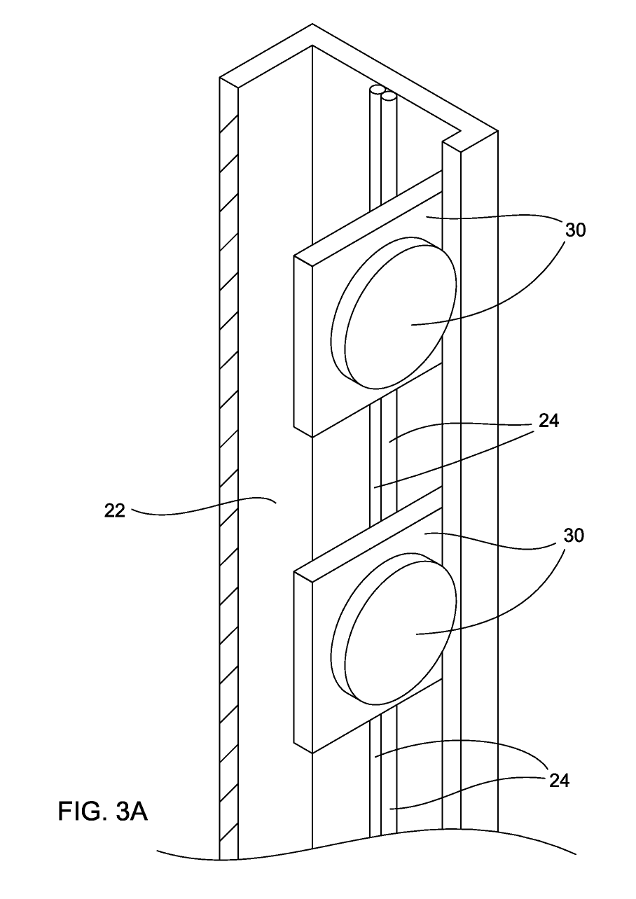

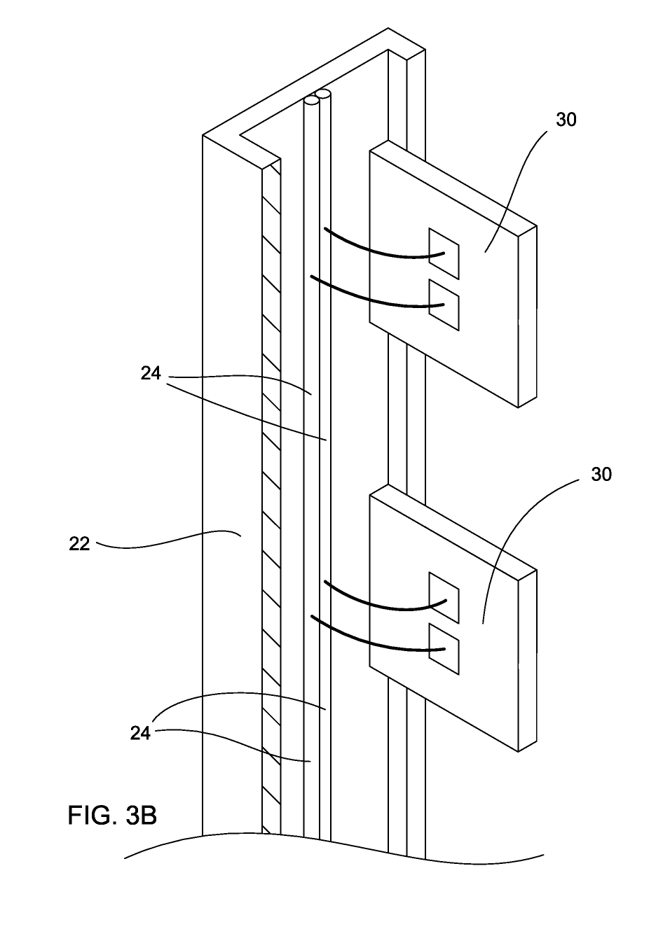

The frame members 22 that have integrally mounted lighting elements 30 can also include an integral power source for providing electrical power to the lighting elements 30. In one example, particularly if LED lighting elements 30 are employed, the power source can include one or more batteries integrally mounted in or on the frame member 22. In certain examples, a dedicated battery can be incorporated into each one of the lighting elements 30; each battery can be replaceable independently of its corresponding lighting element 30, or the battery and corresponding lighting element 30 can be integrated so that they must be replaced together. In another example, one battery can provide power for multiple lighting elements 30 (limited to a single frame member 22 or across multiple frame members 22), and that battery typically would be integrally mounted on or within the frame member 22 independently of the lighting elements 30. If more than one lighting element 30 draws power from one battery, then electrical conductors 24 typically are integrally mounted on or within the corresponding frame member 22 to deliver electrical power from that battery to each lighting element 30. Wires 24 are shown in the examples of FIGS. 3A, 3B, 4, and 5. In another example, an arrangement of conductors similar to those employed in household track lighting can be employed. Any other suitable type or arrangement of electrical conductors 24 integrally mounted on or within the corresponding frame member 22 can be employed.

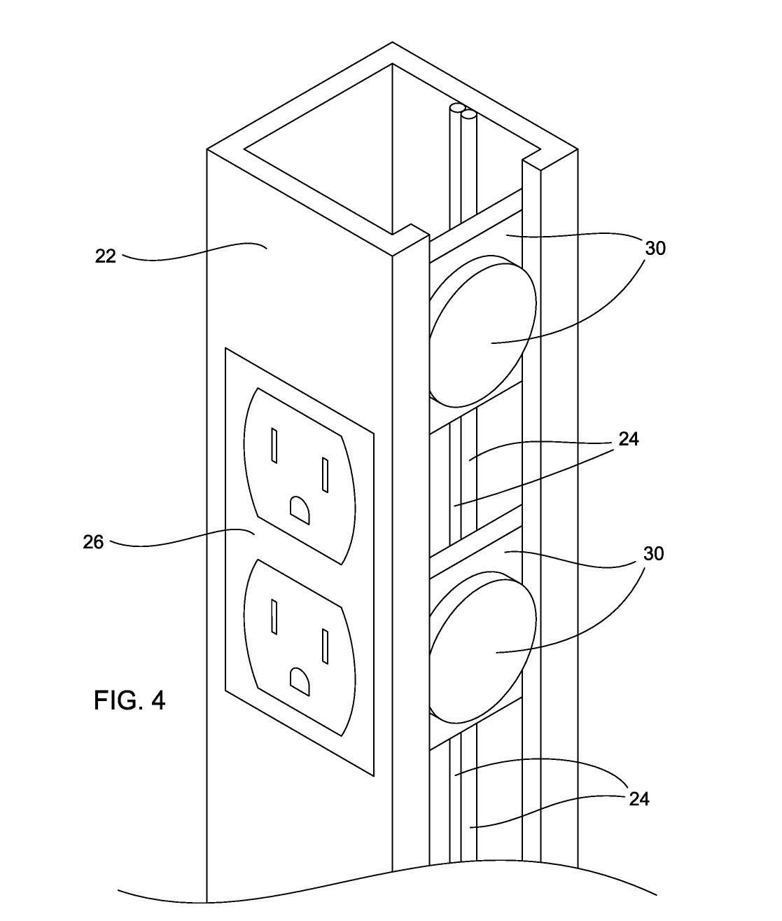

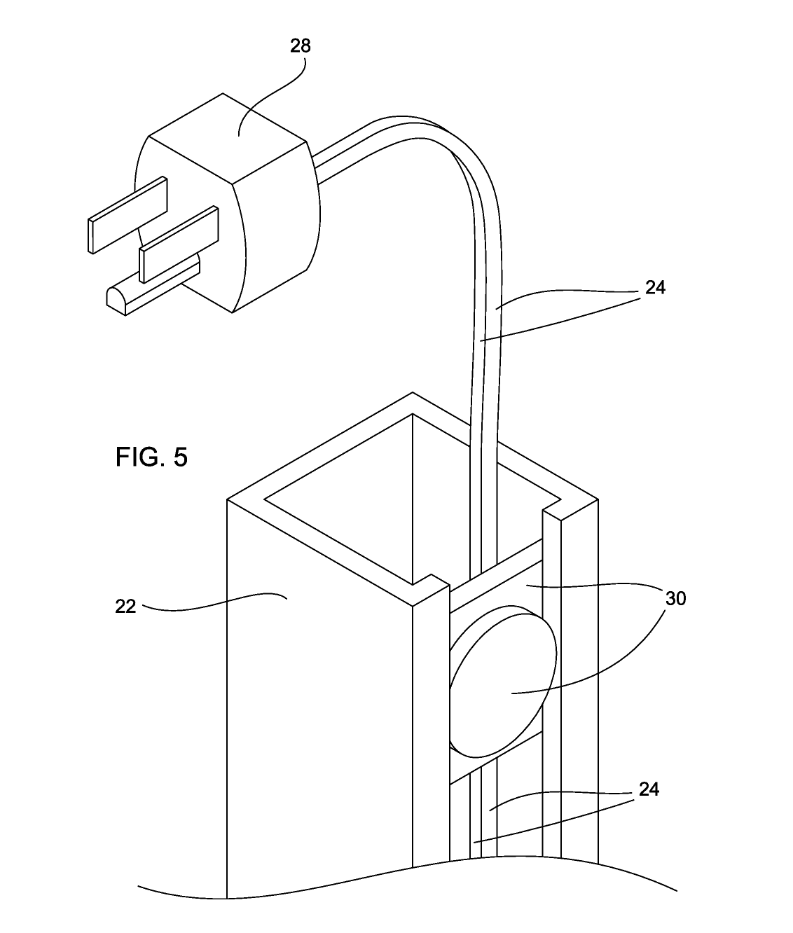

Instead or in addition, in other examples electrical conductors 24 can be arranged to connect the corresponding lighting element(s) 30 to an external power source (not shown; e.g., an external battery, a generator, an electrical outlet connected to a power grid, and so on). A connector 28 arranged for that purpose (e.g., a standard three-pronged plug for a wall outlet or extension cord) is illustrated schematically in FIG. 5; other suitable types or arrangements of such an external connector 28 can be employed. In examples employing an external power source wherein two or more frame members 22 have integrally mounted lighting elements 30, not all of those frame members must necessarily be connected directly to the external power source. For example, the conductors 24 and connectors 28 of those frame members 22 can be connected to one another in series and only one connector 28 connected directly to the external power source, much in the same way that strings of decorative holiday lights are “daisy-chained” together for connection to a single wall outlet.

If a connection to an outside power source is employed, in some of those examples batteries can be employed as well, and in some of those examples that batteries can be rechargeable. Rechargeable batteries (if present) can be recharged by connecting them to an external power source using connector 28 and conductors 24. The presence of batteries in those examples can be useful if the structure is deployed in an area where providing an external power source is difficult or can only be achieved intermittently. The presence of batteries can also act as a backup power supply for the lighting elements 30 in the event of a failure of the external power source (e.g., a power outage or generator failure).

Any suitable mechanism or arrangement can be employed for controlling the lighting elements 30, e.g., any suitable manual or automatic switch for turning the lights on or off. One control mechanism can be connected to control all of the lighting elements 30 together; alternatively, separate control elements can be provided for individual lighting elements 30. In some examples the lighting members 30 can be controlled simply by connecting or disconnecting the external power source.

In some examples, one or more frame members 22 can include one or more integrally mounted auxiliary electrical connectors 26 (e.g., a standard three-pronged outlet or a USB charging port), as illustrated schematically in FIG. 4; other suitable types or arrangements of such an integrally mounted auxiliary electrical connector 26 can be employed. An auxiliary electrical connector 26 (if present) can be used in some examples to connect an additional electrical device to the external power source via electrical conductors 24 and connector 28. In some examples, auxiliary electrical connector 26 can be employed to connect the additional electrical device to one or more integrally mounted batteries (if present).

The presence of lighting elements 30 integrally mounted on one or more of the frame members 22 can be advantageous when erecting or collapsing the collapsible structure 10 at night or under low-light conditions. If the lighting elements 30 are battery powered or can be connected to an external power source, then they can make the corresponding frame members 22 highly visible and also provide at least partial illumination of the deployment area, enhancing safety and efficiency of the erecting or collapsing procedure.

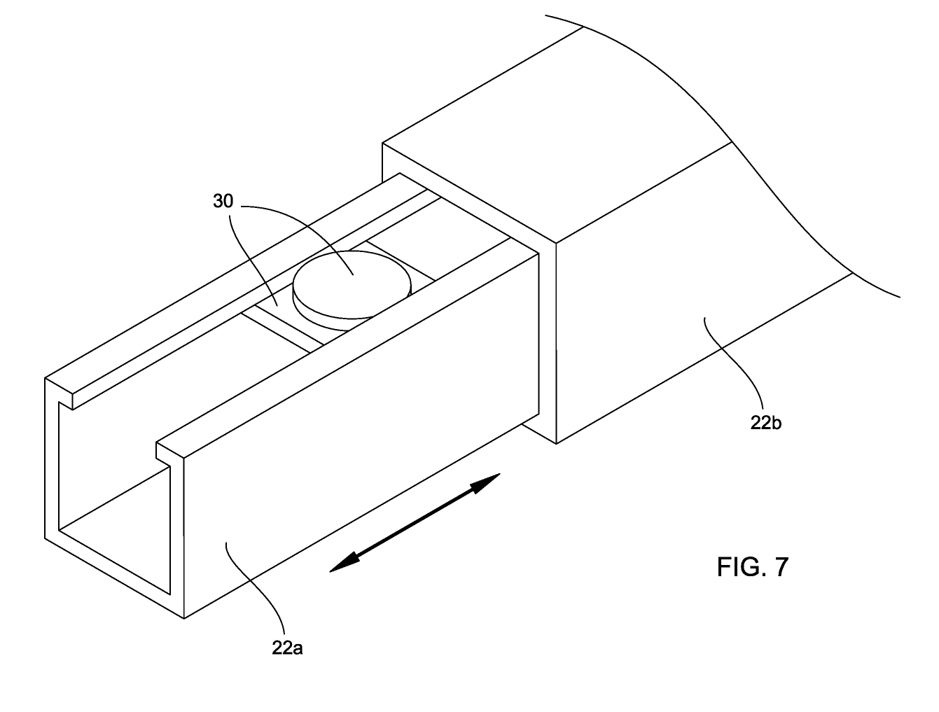

In the example of FIG. 7, the frame member 22 comprises telescoping inner and outer frame members 22a and 22b, respectively. In the example of FIG. 7 the inner and outer frame members 22a/22b are generally rectangular in cross section, however, any cross sectional shape or arrangement can be employed (e.g., rectangular, circular, oval, polygonal, and so forth). The telescoping members 22a/22b are moveable between an extended, deployed configuration and a retracted, non-deployed configuration. The lighting elements 30 can be integrally mounted on the inner frame member 22a. With the frame members 22a/22b in the extended configuration, the lighting elements 30 are exposed outside the outer frame member 22b; with the frame members 22a/22b in the retracted configuration, the lighting elements 30 are enclosed within the outer frame member 22b. The exemplary arrangement of FIG. 7 protects the lighting elements 30 when the collapsible structure is collapsed and transported to a different location (presumably with the inner and outer frame members 22a/22b in the retracted configuration). The inner and outer frame members 22a/22b are moved to the extended configuration for erecting the collapsible structure 10.

In addition to the preceding, the following examples fall within the scope of the present disclosure or appended claims:

### EXAMPLE 1

A collapsible structure comprising: a plurality of elongated frame members arranged to be assembled together in a deployed arrangement to define a volume of the structure; and one or more lighting elements integrally mounted on one or more of the frame members and arranged to illuminate, with the frame members in the deployed arrangement, at least a portion of the structure volume or an area around the structure.

### EXAMPLE 2

The collapsible structure of Example 1 wherein the one or more lighting elements comprise one or more light-emitting diodes.

### EXAMPLE 3

The collapsible structure of any one of Examples 1 or 2 wherein one or more of the frame members have generally U-shaped cross sections, and the one or more lighting elements are integrally mounted within the U-shaped cross sections of the corresponding one or more frame members.

### EXAMPLE 4

The collapsible structure of any one of Examples 1-3 wherein one or more of the plurality of frame members include an integral power source connected to one or more of the corresponding lighting elements.

### EXAMPLE 5

The collapsible structure of Example 4 wherein the integral power source includes one or more electrical conductors integrally mounted on or within the corresponding frame member that are arranged to connect the corresponding one or more lighting elements to an external power source.

### EXAMPLE 6

### The collapsible structure of Example 4 wherein the integral power source includes one or more batteries integrally mounted on or within the corresponding frame member.

### EXAMPLE 7

The collapsible structure of Example 6 wherein the integral power source further includes one or more electrical conductors integrally mounted on or within the corresponding frame member that are arranged to connect the one or more batteries to an external power source, and the one or more batteries and the one or more electrical conductors are arranged so as to charge the one or more batteries with the one or more batteries connected to the external power source by the one or more electrical conductors.

### EXAMPLE 8

The collapsible structure of any one of Examples 5 or 7 wherein the corresponding frame member includes one or more integrally mounted electrical connectors arranged to connect an additional electrical device to the external power source through the one or more electrical conductors.

### EXAMPLE 9

The collapsible structure of any one of Examples 1-8 wherein: one or more of the plurality of frame members comprise corresponding pairs of telescoping inner and outer frame members movable between an extended, deployed configuration and a retracted, non-deployed configuration; the one or more lighting elements are integrally mounted on the one or more corresponding inner frame members; and the one or more lighting elements and the one or more corresponding frame members are arranged so that, with the corresponding frame members in the extended configuration, the lighting elements are exposed outside the corresponding outer frame members and, with the corresponding frame members in the retracted configuration, the lighting elements are enclosed within the corresponding outer frame members.

### EXAMPLE 10

The collapsible structure of any one of Examples 1-9 further comprising one or more panels arranged to be attached, with the frame members in the deployed arrangement, to one or more of the frame members so as to at least partially enclose the structure volume.

### EXAMPLE 11

The collapsible structure of Example 10 wherein the one or more panels are foldable.

### EXAMPLE 12

The collapsible structure of any one of Examples 1-11 wherein at least two of the frame members are connected by an articulated joint so as to enable those at least two articulated frame members to assume a first relative orientation in the deployed arrangement and to assume a second, different relative orientation in a non-deployed arrangement.

### EXAMPLE 13

The collapsible structure of any one of Examples 1-12 wherein at least one of the frame members is arranged to be connected, with the plurality of frame members in the deployed arrangement, to at least one other frame member and to be separated, with the plurality of frame members in a non-deployed arrangement, from the at least one other frame member.

### EXAMPLE 14

An article comprising: an elongated frame member that is arranged to be assembled together with a plurality of other elongated frame members in a deployed arrangement to define a volume of a collapsible structure; and one or more lighting elements integrally mounted on the frame members and arranged to illuminate, with the frame member and the other frame members in the deployed arrangement, at least a portion of the structure volume or an area around the structure.

### EXAMPLE 15

The article of Example 14 wherein the one or more lighting elements comprise one or more light-emitting diodes.

### EXAMPLE 16

The article of any one of Example 14 or 15 wherein the frame member has a generally U-shaped cross section, and the one or more lighting elements are integrally mounted within the U-shaped cross section of the frame member.

### EXAMPLE 17

The article of any one of Examples 14-16 wherein the frame member includes an integral power source connected to one or more of the corresponding lighting elements.

### EXAMPLE 18

The article of Example 17 wherein the integral power source includes one or more electrical conductors integrally mounted on or within the frame member that is arranged to connect the one or more lighting elements to an external power source.

### EXAMPLE 19

The article of Example 17 wherein the integral power source includes one or more batteries integrally mounted on or within the frame member.

### EXAMPLE 20

The article of Example 19 wherein the integral power source further includes one or more electrical conductors integrally mounted on or within the frame member that are arranged to connect the one or more batteries to an external power source, and the one or more batteries and the one or more electrical conductors are arranged so as to charge the one or more batteries with the one or more batteries connected to the external power source by the one or more electrical conductors.

### EXAMPLE 21

The article of any one of Examples 18 or 20 wherein the frame member includes one or more integrally mounted electrical connectors arranged to connect an additional electrical device to the external power source through the one or more electrical conductors.

### EXAMPLE 22

The article of any one of Examples 14-21 wherein: the frame member comprises a pair of telescoping inner and outer frame members movable between an extended, deployed configuration and a retracted, non-deployed configuration; the one or more lighting elements are integrally mounted on the inner frame member; and the one or more lighting elements and the frame member are arranged so that, with the frame member in the extended configuration, the lighting elements are exposed outside the outer frame member and, with the frame member in the retracted configuration, the lighting elements are enclosed within the outer frame member.

### EXAMPLE 23

A method comprising assembling together into a deployed arrangement a plurality of elongated frame members so as to define a volume of a collapsible structure, wherein one or more lighting elements are integrally mounted on one or more of the frame members and arranged to illuminate, with the frame members in the deployed arrangement, at least a portion of the structure volume or an area around the structure.

### EXAMPLE 24

The method of Example 23 wherein the one or more lighting elements comprise one or more light-emitting diodes.

### EXAMPLE 25

The method of any one of Examples 23 or 24 wherein one or more of the frame members have generally U-shaped cross sections, and the one or more lighting elements are integrally mounted within the U-shaped cross sections of the corresponding one or more frame members.

### EXAMPLE 26

The method of any one of Examples 23-25 wherein one or more of the plurality of frame members include an integral power source connected to one or more of the corresponding lighting elements.

### EXAMPLE 27

The method of Example 26 wherein the integral power source includes one or more electrical conductors integrally mounted on or within the corresponding frame member that are arranged to connect the corresponding one or more lighting elements to an external power source.

### EXAMPLE 28

The method of Example 26 wherein the integral power source includes one or more batteries integrally mounted on or within the corresponding frame member.

### EXAMPLE 29

The method of Example 28 wherein the integral power source further includes one or more electrical conductors integrally mounted on or within the corresponding frame member that are arranged to connect the one or more batteries to an external power source, and the one or more batteries and the one or more electrical conductors are arranged so as to charge the one or more batteries with the one or more batteries connected to the external power source by the one or more electrical conductors.

### EXAMPLE 30

The method of Example 27 wherein the corresponding frame member includes one or more integrally mounted electrical connectors arranged to connect an additional electrical device to the external power source through the one or more electrical conductors.

### EXAMPLE 31

The method of any one of Examples 26-30 further comprising applying power to the one or more lighting elements so as to at least partly illuminate a deployment area while assembling together into the deployed arrangement the plurality of frame members.

### EXAMPLE 32

The method of any one of Examples 23-31 wherein: one or more of the plurality of frame members comprise corresponding pairs of telescoping inner and outer frame members movable between an extended, deployed configuration and a retracted, non-deployed configuration; the one or more lighting elements are integrally mounted on the one or more corresponding inner frame members; and the one or more lighting elements and the one or more corresponding frame members are arranged so that, with the corresponding frame members in the extended configuration, the lighting elements are exposed outside the corresponding outer frame members and, with the corresponding frame members in the retracted configuration, the lighting elements are enclosed within the corresponding outer frame members.

### EXAMPLE 33

The method of Example 32 further comprising moving the one or more pairs of inner and outer frame members into the extended, deployed configuration.

### EXAMPLE 34

The method of any one of Examples 23-33 further comprising attaching, with the frame members in the deployed arrangement, one or more panels to one or more of the frame members so as to at least partially enclose the structure volume.

### EXAMPLE 35

The method of Example 34 wherein the one or more panels are foldable.

### EXAMPLE 36

The method of any one of Examples 23-35 wherein at least two of the frame members are connected by an articulated joint so as to enable those at least two articulated frame members to assume a first relative orientation in the deployed arrangement and to assume a second, different relative orientation in a non-deployed arrangement.

### EXAMPLE 37

The method of any one of Examples 23-36 wherein at least one of the frame members is arranged to be connected, with the plurality of frame members in the deployed arrangement, to at least one other frame member and to be separated, with the plurality of frame members in a non-deployed arrangement, from the at least one other frame member.

It is intended that equivalents of the disclosed exemplary embodiments and methods shall fall within the scope of the present disclosure or appended claims. It is intended that the disclosed exemplary embodiments and methods, and equivalents thereof, may be modified while remaining within the scope of the present disclosure or appended claims.

In the foregoing Detailed Description, various features may be grouped together in several exemplary embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of a single disclosed exemplary embodiment. Thus, the appended claims are hereby incorporated into the Detailed Description, with each claim standing on its own as a separate disclosed embodiment. However, the present disclosure shall also be construed as implicitly disclosing any embodiment having any suitable set of one or more disclosed or claimed features (i.e., sets of features that are not incompatible or mutually exclusive) that appear in the present disclosure or the appended claims, including those sets that may not be explicitly disclosed herein. It should be further noted that the scope of the appended claims do not necessarily encompass the whole of the subject matter disclosed herein.

For purposes of the present disclosure and appended claims, the conjunction “or” is to be construed inclusively (e.g., “a dog or a cat” would be interpreted as “a dog, or a cat, or both”; e.g., “a dog, a cat, or a mouse” would be interpreted as “a dog, or a cat, or a mouse, or any two, or all three”), unless: (i) it is explicitly stated otherwise, e.g., by use of “either . . . or,” “only one of,” or similar language; or (ii) two or more of the listed alternatives are mutually exclusive within the particular context, in which case “or” would encompass only those combinations involving non-mutually-exclusive alternatives. For purposes of the present disclosure or appended claims, the words “comprising,” “including,” “having,” and variants thereof, wherever they appear, shall be construed as open ended terminology, with the same meaning as if the phrase “at least” were appended after each instance thereof.

In the appended claims, if the provisions of 35 USC §112 ¶6 are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC §112 ¶6 are not intended to be invoked for that claim.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. A collapsible structure comprising:
a plurality of elongated frame members arranged to be assembled together in a deployed arrangement to define a volume of the structure; and
one or more lighting elements integrally mounted on one or more of the frame members and arranged to illuminate, with the frame members in the deployed arrangement, at least a portion of the structure volume or an area around the structure.

2. The collapsible structure of claim 1 wherein the one or more lighting elements comprise one or more light-emitting diodes.

3. The collapsible structure of claim 1 wherein one or more of the frame members have generally U-shaped cross sections, and the one or more lighting elements are integrally mounted within the U-shaped cross sections of the corresponding one or more frame members.

4. The collapsible structure of claim 1 wherein one or more of the plurality of frame members include an integral power source connected to one or more of the corresponding lighting elements.

5. The collapsible structure of claim 4 wherein the integral power source includes one or more electrical conductors integrally mounted on or within the corresponding frame member that are arranged to connect the corresponding one or more lighting elements to an external power source.

6. The collapsible structure of claim 4 wherein the integral power source includes one or more batteries integrally mounted on or within the corresponding frame member.

7. The collapsible structure of claim 6 wherein the integral power source further includes one or more electrical conductors integrally mounted on or within the corresponding frame member that are arranged to connect the one or more batteries to an external power source, and the one or more batteries and the one or more electrical conductors are arranged so as to charge the one or more batteries with the one or more batteries connected to the external power source by the one or more electrical conductors.

8. The collapsible structure of claim 5 wherein the corresponding frame member includes one or more integrally mounted electrical connectors arranged to connect an additional electrical device to the external power source through the one or more electrical conductors.

9. The collapsible structure of claim 1 wherein:
one or more of the plurality of frame members comprise corresponding pairs of telescoping inner and outer frame members movable between an extended, deployed configuration and a retracted, non-deployed configuration;
the one or more lighting elements are integrally mounted on the one or more corresponding inner frame members; and
the one or more lighting elements and the one or more corresponding frame members are arranged so that, with the corresponding frame members in the extended configuration, the lighting elements are exposed outside the corresponding outer frame members and, with the corresponding frame members in the retracted configuration, the lighting elements are enclosed within the corresponding outer frame members.

10. The collapsible structure of claim 1 further comprising one or more panels arranged to be attached, with the frame members in the deployed arrangement, to one or more of the frame members so as to at least partially enclose the structure volume.

11. An article comprising:
an elongated frame member that is arranged to be assembled together with a plurality of other elongated frame members in a deployed arrangement to define a volume of a collapsible structure; and
one or more lighting elements integrally mounted on the frame members and arranged to illuminate, with the frame member and the other frame members in the deployed arrangement, at least a portion of the structure volume or an area around the structure.

12. The article of claim 11 wherein the one or more lighting elements comprise one or more light-emitting diodes.

13. The article of claim 11 wherein the frame member has a generally U-shaped cross section, and the one or more lighting elements are integrally mounted within the U-shaped cross section of the frame member.

14. The article of claim 11 wherein the frame member includes an integral power source connected to one or more of the corresponding lighting elements.

15. The article of claim 14 wherein the integral power source includes one or more electrical conductors integrally mounted on or within the frame member that is arranged to connect the one or more lighting elements to an external power source.

16. The article of claim 14 wherein the integral power source includes one or more batteries integrally mounted on or within the frame member.

17. The article of claim 16 wherein the integral power source further includes one or more electrical conductors integrally mounted on or within the frame member that are arranged to connect the one or more batteries to an external power source, and the one or more batteries and the one or more electrical conductors are arranged so as to charge the one or more batteries with the one or more batteries connected to the external power source by the one or more electrical conductors.

18. The article of claim 15 wherein the frame member includes one or more integrally mounted electrical connectors arranged to connect an additional electrical device to the external power source through the one or more electrical conductors.

19. The article of claim 11 wherein:
the frame member comprises a pair of telescoping inner and outer frame members movable between an extended, deployed configuration and a retracted, non-deployed configuration;
the one or more lighting elements are integrally mounted on the inner frame member; and
the one or more lighting elements and the frame member are arranged so that, with the frame member in the extended configuration, the lighting elements are exposed outside the outer frame member and, with the frame member in the retracted configuration, the lighting elements are enclosed within the outer frame member.

20. A method comprising assembling together into a deployed arrangement a plurality of elongated frame members so as to define a volume of a collapsible structure, wherein one or more lighting elements are integrally mounted on one or more of the frame members and arranged to illuminate, with the frame members in the deployed arrangement, at least a portion of the structure volume or an area around the structure.

21. The method of claim 20 wherein one or more of the plurality of frame members include an integral power source connected to one or more of the corresponding lighting elements.

22. The method of claim 21 further comprising applying power to the one or more lighting elements so as to at least partly illuminate a deployment area while assembling together into the deployed arrangement the plurality of frame members.

23. The method of claim 20 further comprising attaching, with the frame members in the deployed arrangement, one or more panels to one or more of the frame members so as to at least partially enclose the structure volume.
